(19) United States
(12) Patent Application Publication
(10) Pub. No.: US 2017/0117192 A1
(43) Pub. Date: Apr. 27, 2017

(54) SEMICONDUCTOR DEVICE AND METHOD OF FABRICATING THE SAME

(71) Applicant: Samsung Electronics Co., Ltd., Suwon-si (KR)

(72) Inventors: Sun-Ki Min, Seoul (KR); Gi-Gwan PARK, Suwon-si (KR); Sang-Koo KANG, Seoul (KR); Sung-Sao KIM, Seoul (KR); Ju-Youn KIM, Suwon-si (KR); Koung-Min RYU, Hwaseong-si (KR); Jae-Hoon LEE, Hwaseong-si (KR); Tae-Won HA, Seongnam-si (KR)

(73) Assignee: Samsung Electronics Co., Ltd., Suwon-si (KR)

(21) Appl. No.: 15/215,951

(22) Filed: Jul. 21, 2016

(30) Foreign Application Priority Data
Oct. 26, 2015 (KR) 10-2015-0148710

(51) Int. Cl. H01L 21/8238; H01L 29/78; H01L 27/092

(52) U.S. Cl. CPC H01L 21/823864; H01L 27/0924; H01L 29/7854; H01L 21/823821; H01L 21/82385; H01L 29/0653

(57) ABSTRACT

A semiconductor device may include a first gate electrode being formed on a substrate and having a first ratio of a width of an upper surface to a width of a lower surface, a second gate electrode being formed on the substrate and having a second ratio of the width of the upper surface to the width of the lower surface, wherein the second ratio is less than the first ratio, a first gate spacer being formed on a sidewall of the first gate electrode, a second gate spacer being formed on a sidewall of the second gate electrode and an interlayer insulating film covering the first gate spacer and the second gate spacer.

### CROSS-REFERENCE TO RELATED APPLICATION

This application claims priority from Korean Patent Application No. 10-2015-0148710 filed on Oct. 26, 2015 in the Korean Intellectual Property Office, and all the benefits accruing therefrom under 35 U.S.C. 119, the contents of which in its entirety are herein incorporated by reference.

### BACKGROUND

1. Technical Field

Example embodiments relate to a semiconductor device and/or a fabricating method thereof.

2. Description of the Related Art

For semiconductor device density enhancement, the multigate transistor has been suggested as one of the scaling technologies, according to which a multi-channel active pattern (or silicon body) in a fin or nanowire shape is formed on a substrate, with gates then being formed on a surface of the multi-channel active pattern.

This multigate transistor may allow for relatively easy scaling, as it uses a three-dimensional channel. Further, current control capability may be enhanced without requiring increased gate length of the multigate transistor. Furthermore, it is possible to effectively suppress short channel effect (SCE), which is the phenomenon that the electric potential of the channel region is influenced by the drain voltage.

### SUMMARY

Some example embodiments relate to a semiconductor device having enhanced performance by utilizing stress of an insulating film.

Other example embodiments relate to a method of fabricating a semiconductor device having enhanced performance by utilizing stress of an insulating film.

According to an example embodiment of the inventive concepts, there is provided a semiconductor device.

In some example embodiments, the semiconductor device may include a first gate electrode on a substrate, the first gate electrode having a first ratio of a width of an upper surface thereof to a width of a lower surface thereof; a second gate electrode on the substrate, the second gate electrode having a second ratio of a width of an upper surface thereof to a width of a lower surface thereof such that the second ratio is less than the first ratio; a first gate spacer on a sidewall of the first gate electrode; a second gate spacer on a sidewall of the second gate electrode; and an interlayer insulating film at least partially covering the first gate spacer and the second gate spacer.

According to some other example embodiments of the inventive concepts, the semiconductor device may include a first gate electrode on a substrate such that a width of the first gate electrode increases with increasing distance from the substrate; a second gate electrode on the substrate such that a width of the second gate electrode decreases with increasing distance from the substrate; a first gate spacer on a sidewall of the first gate electrode, the first gate spacer configured to exert a first tensile stress on the first gate electrode; a second gate spacer on a sidewall of the second gate electrode, the second gate spacer configured to exert a second tensile stress on the second gate electrode such that the first tensile stress exerted on the first gate electrode is greater than the second tensile stress exerted on the second gate electrode; and an interlayer insulating film at least partially covering the first gate spacer and the second gate spacer.

According to some other example embodiments of the inventive concepts, the semiconductor device may include a first gate spacer on sidewalls of a first gate electrode such that the first gate spacer is configured to exert a first tensile stress on the first gate electrode; a second gate spacer on sidewalls of a second gate electrode such that the first gate spacer is configured to exert a second tensile stress on the second gate electrode; and an interlayer insulating film at least partially covering the first gate spacer and the second gate spacer such that the interlayer insulating film is configured to exert a first compressive stress on the first gate electrode and a second compressive stress on the second gate electrode.

### BRIEF DESCRIPTION OF THE DRAWINGS

The above and other objects, features and advantages of the example embodiments will become more apparent to those of ordinary skill in the art by describing in detail some example embodiments thereof with reference to the accompanying drawings, in which:

FIG. 1 is a top view provided to explain a semiconductor device according to some example embodiments;

FIG. 2 is a cross sectional view taken on line A-A of FIG. 1;

FIG. 3 illustrates a first gate spacer from which the first gate electrode of FIG. 2 is omitted;

FIG. 4 illustrates only the first gate electrode of FIG. 2 separately;

FIG. 5 illustrates a second gate spacer from which the second gate electrode of FIG. 2 is omitted;

FIG. 6 illustrates only the second gate electrode of FIG. 2 separately;

FIGS. 7A to 8B are cross sectional views taken on line B-B of FIG. 1;

FIGS. 9A to 10B are cross sectional views taken on line C-C of FIG. 1;

FIG. 11 is a view provided to explain a semiconductor device according to some example embodiments;

FIG. 12 is a view provided to explain a semiconductor device according to some example embodiments;

FIG. 13 is a view provided to explain a semiconductor device according to some example embodiments;

FIGS. 14 to 19 are views illustrating intermediate stages of fabrication, provided to explain a method of fabricating a semiconductor device according to some example embodiments;

FIG. 20 is a view illustrating intermediate stages of fabrication, provided to explain a method of fabricating a semiconductor device according to some example embodiments;

FIG. 21 is a view illustrating intermediate stages of fabrication, provided to explain a method of fabricating a semiconductor device according to some example embodiments;

FIGS. 22 to 26 are views illustrating intermediate stages of fabrication, provided to explain a method of fabricating a semiconductor device according to some example embodiments; and

FIG. 27 is a block diagram of a SoC system including a semiconductor device according to example embodiments.

### DETAILED DESCRIPTION

Example embodiments of the inventive concepts will now be described more fully hereinafter with reference to the accompanying drawings, in which some example embodiments are shown. Example embodiments may, however, be embodied in different forms and should not be construed as limited to the example embodiments set forth herein.

Rather, these example embodiments are provided so that this disclosure will be thorough and complete, and will fully convey the scope of the example embodiments to those skilled in the art. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the example embodiments.

The use of the terms “a” and “an” and “the” and similar referents in the context of describing the example embodiments (especially in the context of the following claims) are to be construed to cover both the singular and the plural, unless otherwise indicated herein or clearly contradicted by context. The terms “comprising,” “having” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which these example embodiments belong. It is noted that the use of any and all examples, or example terms provided herein is intended merely to better illuminate the example embodiments and is not a limitation on the scope of the example embodiments unless otherwise specified. Further, unless defined otherwise, all terms defined in generally used dictionaries may not be overly interpreted.

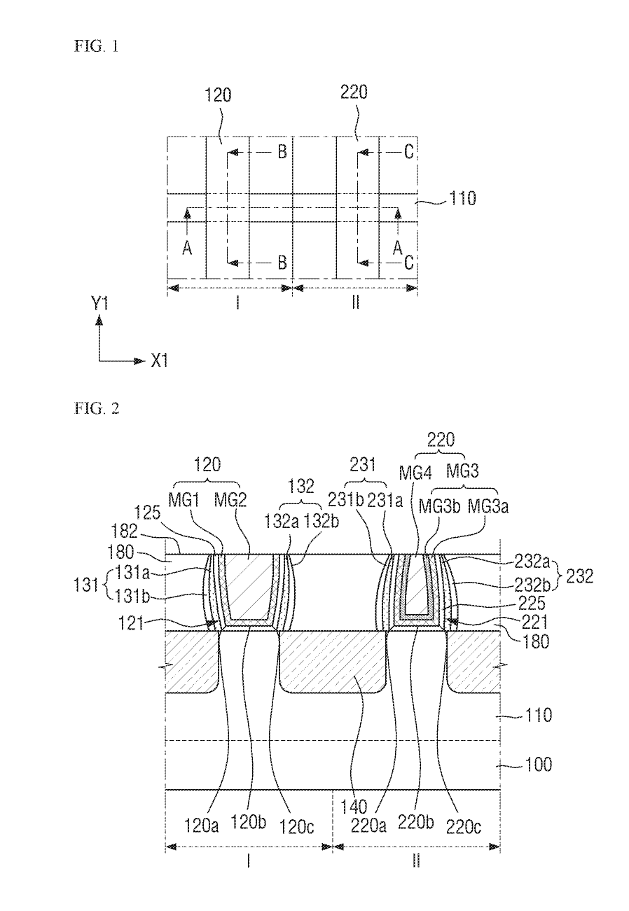

Hereinbelow, a semiconductor device according to an example embodiment will be described with reference to FIGS. 1 to 10A.

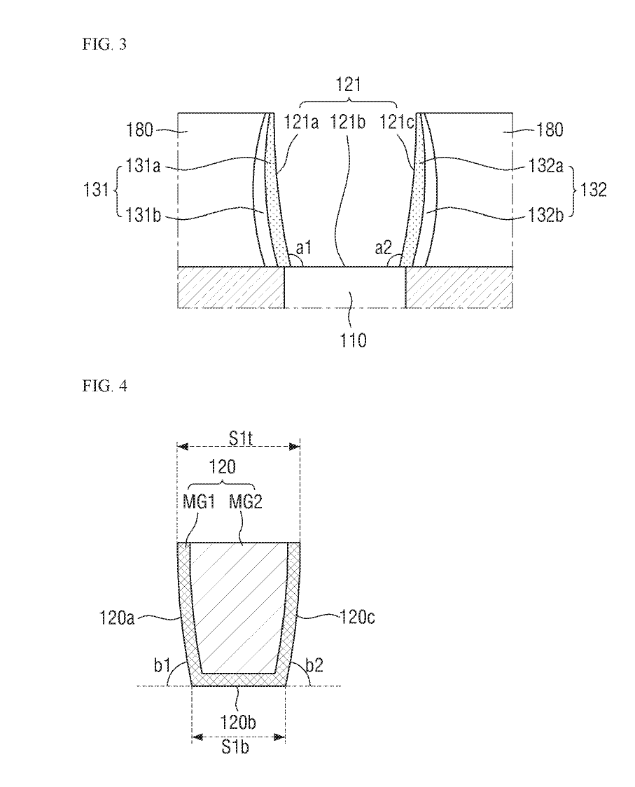

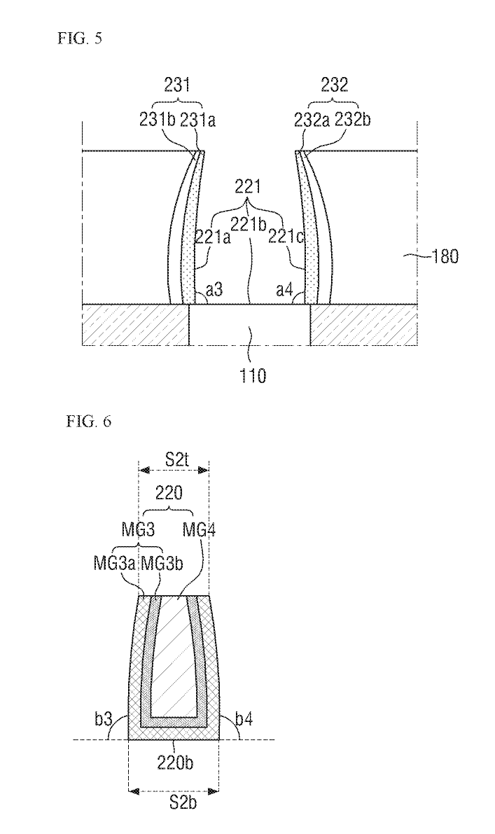

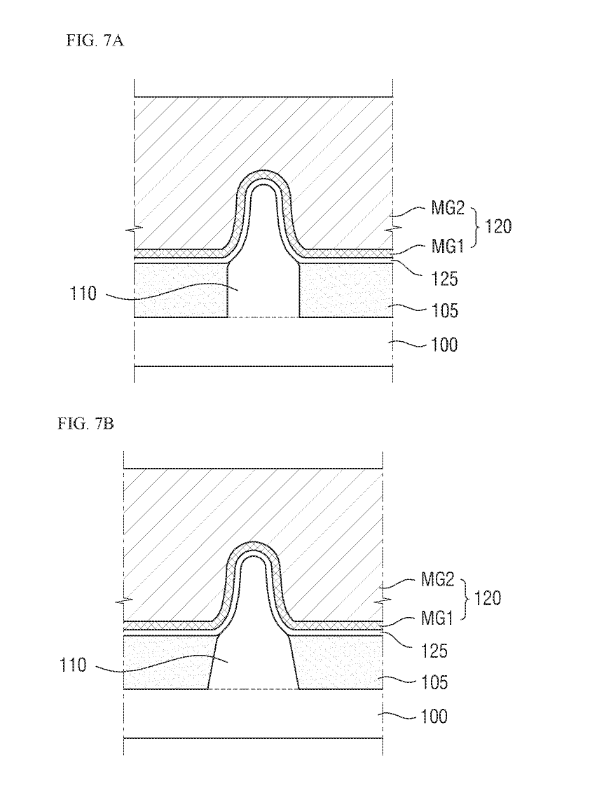

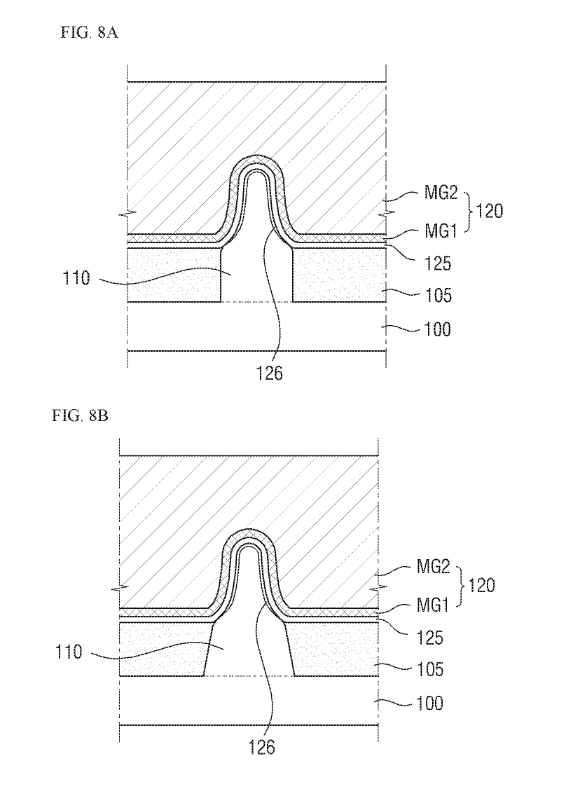

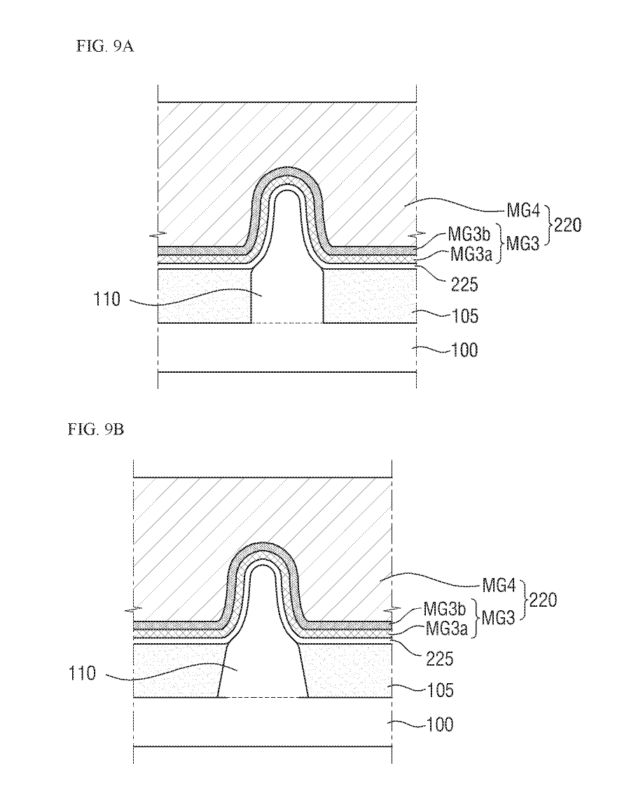

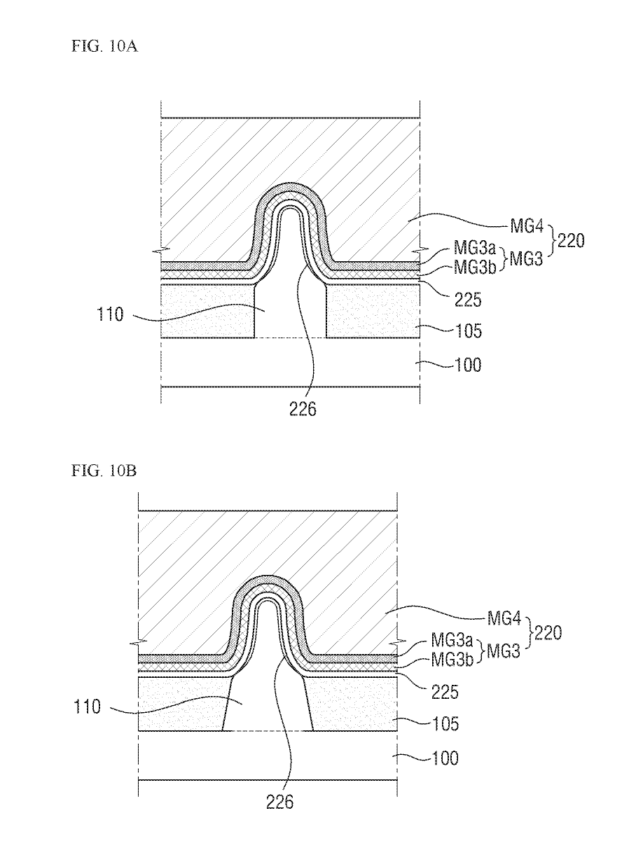

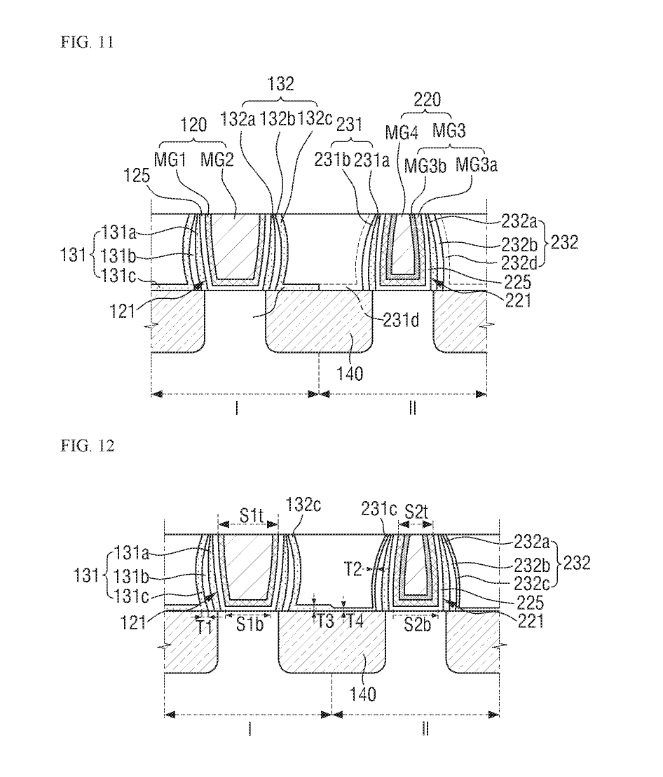

FIG. 1 is a top view provided to explain a semiconductor device according to some example embodiments, and FIG. 2 is a cross sectional view taken on line A-A of FIG. 1. FIG. 3 illustrates a first gate spacer from which the first gate electrode of FIG. 2 is omitted, and FIG. 4 illustrates only the first gate electrode of FIG. 2 separately. FIG. 5 illustrates a second gate spacer from which the second gate electrode of FIG. 2 is omitted, and FIG. 6 illustrates only the second gate electrode of FIG. 2 separately. FIGS. 7A to 8B are cross sectional views taken on line B-B of FIG. 1, and FIGS. 9A to 10B are cross sectional views taken on line C-C of FIG. 1.

As illustrated in the drawings, a semiconductor device may include a channel region in a fin-type pattern shape therein, but example embodiments are not limited thereto. For example, the semiconductor device may include a channel region in a wire-pattern shape instead of the fin-type pattern shape.

Further, although it is described below that a semiconductor device includes a fin type field effect transistor (FINFET) utilizing a fin-type pattern, example embodiments are not limited thereto. For example, a semiconductor device according to example embodiments may include a planar transistor.

Referring to FIGS. 1 to 4D, the semiconductor device according to some example embodiments may include a first fin-type pattern 110, a first gate electrode 120, a second gate electrode 220, first gate spacers 131, 132, second gate spacers 231, 232, and an interlayer insulating film 180.

A substrate 100 may be a bulk silicon or a silicon-on-insulator (SOI), for example. Alternatively, the substrate 100 may be a silicon substrate, or may include other substance such as silicon germanium, indium antimonide, lead telluride compound, indium arsenide, indium phosphide, gallium arsenide, or gallium antimonide. Alternatively, the substrate 100 may be a base substrate having an epitaxial layer formed thereon.

The substrate 100 may include a first region I and a second region II. The first region I and the second region II may be regions adjacent to each other. However, example embodiments are not limited to the example given above. The first gate electrode 120 (to be described) may be formed in the first region (I), and the second gate electrode 220 (to be described) may be formed in the second region II.

The first fin-type pattern 110 may protrude from the substrate 100. The first fin-type pattern 110 may extend longitudinally in a first direction X1.

The first fin-type pattern 110 refers to an active pattern used in a multigate transistor. Accordingly, the first fin-type pattern 110 may be formed as the channels are connected with each other along three surfaces of the fin, or alternatively, the channels may be formed on two opposing surfaces of the fin.

The first fin-type pattern 110 may be a part of the substrate 100, and may include an epitaxial layer grown on the substrate 100.

The first fin-type pattern 110 may include an element semiconductor material such as silicon or germanium, for example. Further, the first fin-type pattern 110 may include a compound semiconductor such as, for example, IV-IV group compound semiconductor or III-V group compound semiconductor.

Specifically, take the IV-IV group compound semiconductor for instance, the first fin-type pattern 110 may be a binary compound or a ternary compound including, for example, at least two or more of carbon (C), silicon (Si), germanium (Ge), or tin (Sn), or the above-mentioned binary or ternary compound doped with IV group element.

Take the III-V group compound semiconductor for instance, the first fin-type pattern 110 may be one of a binary compound, a ternary compound or a quaternary compound which is formed by a combination of a III group element which may be at least one of aluminum (Al), gallium (Ga), or indium (In), with a V group element which may be one of phosphorus (P), arsenic (As) or antimony (Sb).

In the semiconductor device according to example embodiments, the first fin-type pattern 110 may be a silicon fin-type pattern which includes silicon.

A first field insulating film 105 may be formed on the substrate 100. The first field insulating film 105 may partially cover a side surface of the first fin-type pattern 110. Accordingly, an upper surface of the first fin-type pattern 110 may protrude upward higher than an upper surface of the first field insulating film 105 disposed on the long side of the first fin-type pattern 110. The first fin-type pattern 110 may be defined by the first field insulating film 105 on the substrate 100.

The first field insulating film 105 may include, for example, one of oxide film, nitride film, oxynitride film, or a combination thereof.

The first gate electrode 120 may extend in the second direction Y1. The first gate electrode 120 may be formed to intersect the first fin-type pattern 110.

The first gate electrode 120 may be formed on the first fin-type pattern 110 and the first field insulating film 105. The first gate electrode 120 may surround the first fin-type pattern 110 protruding upward higher than the upper surface of the first field insulating film 105.

The first gate electrode 120 may include a first sidewall 120a and a second sidewall 120c opposed to each other. The first gate electrode 120 may include a bottom surface 120b which connects the first sidewall 120a of the first gate electrode with the second sidewall 120c of the first gate electrode, and extend along the upper surface of the first fin-type pattern 110.

The second gate electrode 220 may extend in the second direction Y1. The second gate electrode 220 may be formed on the first fin-type pattern 110 so as to intersect the first fin-type pattern 110.

The second gate electrode 220 may be formed adjacent to the first gate electrode 120. In some example embodiments, other gate electrodes that intersect the first fin-type pattern 110 may not be formed between the second gate electrode 220 and the first gate electrode 120.

The second gate electrode 220 may include a first sidewall 220a and a second sidewall 220c opposed to each other. The second gate electrode 220 may include a bottom surface 220b which connects the first sidewall 220a of the second gate electrode with the second sidewall 220c of the second gate electrode, and extends along the upper surface of the first fin-type pattern 110.

The first gate electrode 120 may include metal layers MG1, MG2. For example, the first gate electrode 120 may include a stack of two or more metal layers MG1, MG2, as illustrated. The first metal layer MG1 plays a role of adjusting a work function, and the second metal layer MG2 plays a role of filling a space defined by the first metal layer MG1.

For example, the first metal layer MG1 may be an N-type work function film. For example, the first metal layer MG1 may include at least one of, for example, TiAl, TiAlN, TaC, TaAlN, TiC, HfSi or a combination thereof, but is not limited thereto. Further, the second metal layer MG2 may include at least one of, for example, W, Al, Cu, Co, Ti, Ta, poly-Si, SiGe or a metal alloy, but is not limited thereto.

The second gate electrode 220 may include metal layers MG3, MG4. For example, the second gate electrode 220 may include a stack of two or more metal layers MG3, MG4, as illustrated. The third metal layer MG3 plays a role of adjusting a work function, and the fourth metal layer MG4 plays a role of filling a space defined by the third metal layer MG3. The third metal layer MG3 may include a first sub-metal layer MG3a and a second sub-metal layer MG3b.

The first sub-metal layer MG3a may be an N-type work function film. For example, the first metal layer MG1 may include at least one of, for example, TiAl, TiAlN, TaC, TaAlN, TiC, HfSi or a combination thereof, but is not limited thereto.

The second sub-metal layer MG3b may be formed on the first sub-metal layer MG3a. The second sub-metal layer may be a P-type work function film. For example, the second sub-metal layer MG3b may include metal nitride. Specifically, in some example embodiments, the second sub-metal layer MG3b may be configured to include at least one of TiN or TaN, for example. More specifically, the second sub-metal layer MG3b may be formed of, for example, a single film consisting of TiN or a double film consisting of a TiN lower film and a TaN upper film, but is not limited thereto.

The first gate electrode 120 and the second gate electrode 220 may each be formed by replacement process (or gate last process), but not limited thereto.

The first gate spacers 131, 132 may be disposed on sidewalls of the first gate electrode 120. The first gate spacers 131, 132 may include a first one-side spacer 131 disposed on the first sidewall 120a of the first gate electrode, and a first other-side spacer 132 disposed on the second sidewall 120c of the first gate electrode.

The first one-side spacer 131 and the first other-side spacer 132 may define a first trench 121. The first sidewall 121a of the first trench may be defined by the first one-side spacer 131, and the second sidewall 121c of the first trench may be defined by the first other-side spacer 132. The bottom surface 121b of the first trench may be defined by connecting the first sidewall 121a of the first trench with the second sidewall 121c of the first trench.

The first gate spacers 131, 132 may include lower portions 131b, 132b, and upper portions 131a, 132a. More specifically, the first one-side spacer 131 may include the lower portion 131b and the upper portion 131a, and the first other-side spacer 132 may include the lower portion 132b and the upper portion 132a.

The second gate spacers 231, 232 may be disposed on sidewalls of the second gate electrode 220. The second gate spacers 231, 232 may include a second one-side spacer 231 disposed on the first sidewall 220a of the second gate electrode, and a second other-side spacer 232 disposed on the second sidewall 220c of the second gate electrode.

The second one-side spacer 231 and the second other-side spacer 232 may define a second trench 221.

The second one-side spacer 231 may include a lower portion 231b and an upper portion 231a, and the second other-side spacer 232 may include a lower portion 232b and an upper portion 232a.

The first gate electrode 120 may be formed by filling the first trench 121 defined by the first gate spacers 131, 132. The second gate electrode 220 may be formed by filling the second trench 221 defined by the second gate spacers 231, 232.

The first gate spacers 131, 132 may include first nitride spacers 131a, 132a and first oxide spacers 131b, 132b. The first nitride spacers 131a, 132a may be formed on the first gate electrode 120, and the first oxide spacers 131b, 132b may be formed on the first nitride spacers 131a, 132a.

The second gate spacers 231, 232 may include second nitride spacers 231a, 232a and second oxide spacers 231b, 232b. The second nitride spacers 231a, 232a may be formed on the second gate electrode 220, and the second oxide spacers 231b, 232b may be formed on the second nitride spacers 231a, 232a.

The first nitride spacers 131a, 132a and the second nitride spacers 231a, 232a may include at least one of silicon nitride (SiN), silicon oxynitride (SiON), silicon oxycarbonitride (SiOCN), or a combination thereof. However, example embodiments are not limited to the example given above.

The first oxide spacers 131b, 132b and the second oxide spacers 231b, 232b may include silicon oxide (SiO₂). However, example embodiments are not limited to the example given above.

A first gate insulating film 125 may be formed between the first fin-type pattern 110 and the first gate electrode 120. The first gate insulating film 125 may be formed along the profile of the first fin-type pattern 110 protruding upward higher than the first field insulating film 105.

The first gate insulating film 125 may be disposed between the first gate electrode 120 and the first field insulating film 105. The first gate insulating film 125 may be formed along the sidewalls and the bottom surface of the first trench 121. The first gate insulating film 125 may be formed between the first gate spacers 131, 132 and the first gate electrode 120.

Further, an interfacial layer 126 may be additionally formed between the first gate insulating film 125 and the first fin-type pattern 110. Although not illustrated, referring to FIG. 2, an interfacial layer may also be additionally formed between the first gate insulating film 125 and the first fin-type pattern 110.

As illustrated in FIGS. 8A and 8B, and 10A and 10B, the interfacial layer 126 may be formed along the profile of the first fin-type pattern 110 which protrudes further than the upper surface of the first field insulating film 105, although example embodiments are not limited thereto.

Further, referring to FIGS. 7B, 8B, 9B and 10B, the sidewall of the first fin-type pattern 110 covered by the first field insulating film 105 may have a slope at an acute angle with respect to the upper surface of the substrate 100. The width of the first fin-type pattern 110 covered by the first field insulating film 105 may decrease with increasing distance from the upper surface of the substrate 100.

The leakage current to the lower portion of the first fin-type pattern 110 may decrease, when the width of the first fin-type pattern 110 covered by the first field insulating film 105 decreases with increasing distance from the upper surface of the substrate 100.

The interfacial layer 126 may extend along the upper surface of the first field insulating film 105 according to a method used for forming the interfacial layer 126.

Hereinbelow, example embodiments are explained by referring to drawings in which illustration of the interfacial layer 126 is omitted for convenience of explanation.

A second gate insulating film 225 may be formed between the first fin-type pattern 110 and the second gate electrode 220. The second gate insulating film 225 may be formed along the sidewalls and the bottom surface of the second trench 221. The second gate insulating film 225 may be formed between the second gate spacers 231, 232 and the second gate electrode 220. Description of the second gate insulating film 225 may be similar to that of the first gate insulating film 125.

The first gate insulating film 125 and the second gate insulating film 225 may include a high-k dielectric material having a higher dielectric constant than a silicon oxide film. For example, the first gate insulating film 125 and the second gate insulating film 225 may include one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but not limited thereto.

First source/drain regions 140 may be formed on both sides of the first gate electrode 120 and on both sides of the second gate electrode 220.

While the first source/drain regions 140 are illustrated as impurity regions formed within the first fin-type pattern 110, example embodiments are not limited thereto. For example, the first source/drain regions 140 may include an epitaxial layer formed on the first fin-type pattern 110 or formed within the first fin-type pattern 110.

Further, the first source/drain regions 140 may be elevated source/drain regions including an upper surface which is protruded upward higher than the upper surface of the first fin-type pattern 110.

The interlayer insulating film 180 may be formed on the substrate 100. The interlayer insulating film 180 may cover the first fin-type pattern 110, the first source/drain regions 140, and the first field insulating film 105.

The interlayer insulating film 180 may surround the sidewalls of the first gate electrode 120 and the second gate electrode 220. More specifically, the interlayer insulating film 180 may surround the outer sidewalls of the first gate spacers 131, 132 and the outer sidewalls of the second gate spacers 231, 232.

As illustrated in FIG. 2, the upper surface of the first gate electrode 120 and the upper surface of the second gate electrode 220 may be positioned on the same plane as the upper surface of the upper interlayer insulating film 182, but example embodiments are not limited thereto.

For example, in order to construct a self aligned contact (SAC) structure, capping patterns may be formed on the upper surfaces of the first gate electrode 120 and the second gate electrode 220, respectively, in which case the upper surface of the first gate electrode 120 and the upper surface of the second gate electrode 220 may be lower than the upper surface of the interlayer insulating film 180.

For example, the interlayer insulating film 180 may include silicon oxide, silicon oxynitride, silicon nitride, flowable oxide (FOX), Tonen silazen (TOSZ), undoped silica glass (USG), borosilica glass (BSG), phosphosilica glass (PSG), borophosphosilica glass (BPSG), plasma enhanced tetraethyl orthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric material, or a combination thereof, but is not limited thereto.

The height from the substrate 100 to the upper surface of the interlayer insulating film 180 may be substantially same as the height from the substrate 100 to the uppermost portions of the first gate spacers 131, 132.

Referring to FIGS. 2 and 3, the first sidewall 121a of the first trench defined by the first one-side spacer 131 may have a slope at a first angle a1 with the bottom surface 121b of the first trench. The second sidewall 121c of the first trench defined by the first other-side spacer 132 may have a slope at a second angle a2 with the bottom surface 121b of the first trench.

The first angle a1 and the second angle a2 may be obtuse angles exceeding a right angle. The width of the first trench 121 may increase with increasing distance from the upper surface of the substrate 100, that is, from the bottom surface 121b of the first trench.

As illustrated in FIG. 3, when the first sidewall 121a of the first trench 121 and the second sidewall 121c of the first trench 121 respectively have slopes at an obtuse angle with the bottom surface 121b of the first trench 121, the degree of tensile stress of the interlayer insulating film 180 and the first gate spacers 131, 132 may be greater than the degree of compressive stress.

The ‘tensile stress’ as used herein refers to the stress of the interlayer insulating film or the spacers of pulling the gate electrode toward the interlayer insulating film or the spacers, and the ‘compressive stress’ as used herein refers to the stress of the interlayer insulating film or the spacers of pushing the gate electrode toward the gate electrode.

Referring to FIGS. 2 and 4, the first sidewall 120a of the first gate electrode may have a slope at a third angle b1 with the bottom surface 120b of the first gate electrode. The second sidewall 120c of the first gate electrode may have a slope at a fourth angle b2 with the bottom surface 120b of the first gate electrode.

With the first sidewall 120a of the first gate electrode opposing the sidewall of the first one-side spacer 131 and the second sidewall 120c of the first gate electrode opposing the sidewall of the first other-side spacer 132, the third angle b1 and the fourth angle b2 may be, like the first angle a1 and the second angle a2, obtuse angles exceeding a right angle.

The width of the first gate electrode 120 may increase with increasing distance from the upper surface of the substrate 100. In other words, the width of the first gate electrode 120 may increase in a direction from the bottom surface 120b of the first gate electrode to the upper surface of the first gate electrode 120.

Unlike the illustration, the point where the first sidewall 120a of the first gate electrode and the bottom surface 120b of the first gate electrode meet, and the point where the second sidewall 120c of the first gate electrode and the bottom surface 120b of the first gate electrode meet may have round shape, but it is apparent that those skilled in the art will still be able to obtain the slope of the first sidewall 120a of the first gate electrode and the slope of the second sidewall 120c of the first gate electrode.

The ratio of the width S1t of the upper surface of the first gate electrode to the width S1b of the lower surface of the first gate electrode may be greater than 1. That is, the width S1b of the lower surface of the first gate electrode may be less than the width S1t of the upper surface of the first gate electrode.

Referring to FIGS. 2 to 5, the first sidewall 221a of the second trench 221 defined by the second one-side spacer 231 may have a slope at a fifth angle a3 with the bottom surface 221b of the second trench 221. The second sidewall 221c of the second trench 221 defined by the second other-side spacer 232 may have a slope at a sixth angle a4 with the bottom surface 221b of the second trench 221.

The fifth angle a3 and the sixth angle a4 may be acute angles less than a right angle. The width of the second trench 221 may increase with decreasing distance from the upper surface of the substrate 100, that is, from the bottom surface 221b of the second trench.

As illustrated in FIG. 5, when the first sidewall 221a of the second trench 221 and the second sidewall 221c of the second trench 221 respectively have slopes at an acute angle with the bottom surface 221b of the second trench, the degree of compressive stress of the interlayer insulating film 180 and the second gate spacers 231, 232 may be greater than the degree of tensile stress.

Referring to FIGS. 2 and 6, the first sidewall 220a of the second gate electrode 220 may have a slope at a seventh angle b3 with the bottom surface 220b of the second gate electrode 220. The second sidewall 220c of the second gate electrode 220 may have a slope at an eighth angle b4 with the bottom surface 220b of the second gate electrode 220.

With the first sidewall 220a of the second gate electrode 220 opposing the sidewall of the second one-side spacer 231, and with the second sidewall 220c of the second gate electrode opposing the sidewall of the second other-side spacer 232, the seventh angle b3 and the eighth angle b4 may be, like the fifth angle a3 and the sixth angle a4, acute angles less than a right angle.

The width of the second gate electrode 220 may decrease with increasing distance from the upper surface of the substrate 100. In other words, the width of the second gate electrode 220 may increase in a direction from the bottom surface 220b of the second gate electrode to the upper surface of the second gate electrode 220.

Unlike the illustration, the point where the first sidewall 220a of the second gate electrode and the bottom surface 220b of the second gate electrode meet, and the point where the second sidewall 220c of the second gate electrode and the bottom surface 220b of the second gate electrode meet may have round shape, but it is apparent that those skilled in the art will still be able to obtain the slope of the first sidewall 220a of the second gate electrode and the slope of the second sidewall 220c of the second gate electrode.

The ratio of the width S2t of the upper surface of the second gate electrode to the width S2b of the lower surface of the second gate electrode may be less than 1. That is, the width S2b of the lower surface of the second gate electrode may be greater than the width S2t of the upper surface of the second gate electrode.

Therefore, the width of the firth gate electrode 120 may increase with increasing distance from the upper surface of the substrate 100, while the width of the second gate electrode 220 may decrease with increasing distance from the upper surface of the substrate 100.

Hereinbelow, it is defined that the sidewall of the trench has a positive slope when the sidewall of the trench has a slope at an obtuse angle with the bottom surface of the trench. Likewise, it is defined that the sidewall of the gate electrode has a positive slope when the sidewall of the gate electrode has a slope at an obtuse angle with the bottom surface of the gate electrode.

In contrast, it is defined that the sidewall of the trench has a negative slope when the sidewall of the trench has a slope at an acute angle with the bottom surface of the trench. Likewise, it is defined that the sidewall of the gate electrode has a negative slope when the sidewall of the gate electrode has a slope at an acute angle with the bottom surface of the gate electrode.

That is, referring to FIG. 2, the first sidewall 120a of the first gate electrode and the second sidewall 120c of the first gate electrode may have positive slopes. Further, the first sidewall 220a of the second gate electrode and the second sidewall 220c of the second gate electrode may have negative slopes.

FIG. 2 illustrates that a ratio of the width S1t of the upper surface of the first gate electrode to the width S1b of the lower surface of the first gate electrode is greater than 1, and a ratio of the width S2t of the upper surface of the second gate electrode to the width S2b of the lower surface of the second gate electrode is less than 1. However, in some other example embodiments, the width S1t of the upper surface of the first gate electrode to the width S1b of the lower surface of the first gate electrode, and the width S2t of the upper surface of the second gate electrode to the width S2b of the lower surface of the second gate electrode, may all be less than 1, or may all be greater than 1. Meanwhile, even in the above-mentioned example, a ratio of the width S1t of the upper surface of the first gate electrode to the width S1b of the lower surface of the first gate electrode may be greater than a ratio of the width S2t of the upper surface of the second gate electrode to the width S2b of the lower surface of the second gate electrode.

According to some example embodiments, it is possible to alleviate processing difficulty which increases due to phenomenon of increasing etch rate in the etch process for the low density of the interlayer insulating film 180. Further, the performance of the semiconductor device can be enhanced by applying compressive stress and tensile stress to the PMOS semiconductor device and the NMOS semiconductor device, respectively.

Specifically, while leakage current will increase according to the active current flowing in the transistor, by the compressive stress and the tensile stress, the increase in the leakage current due to increasing active current can be reduced. Accordingly, the semiconductor device can have greatly enhanced performance.

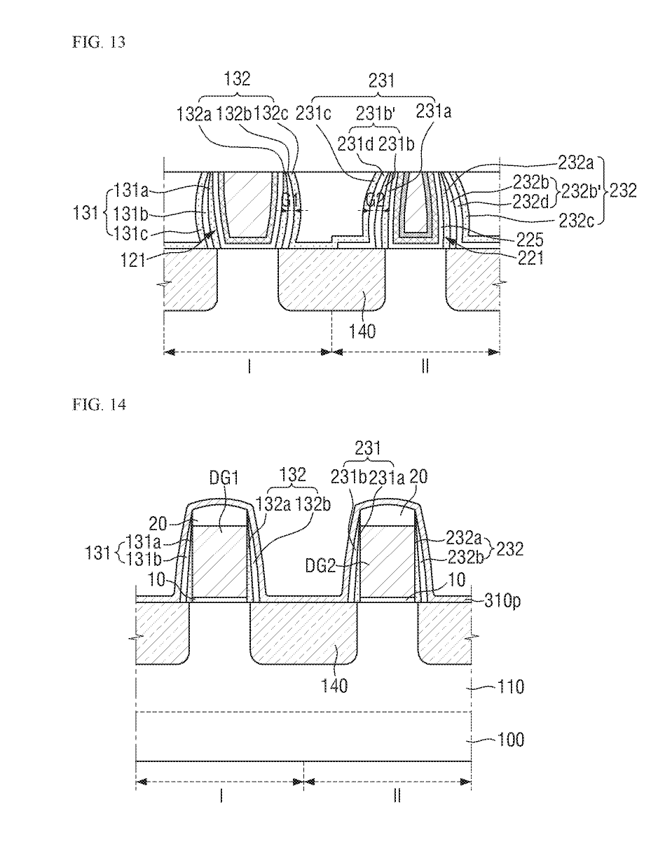

FIG. 11 is a view provided to explain a semiconductor device according to some example embodiments. For convenience of explanation, differences that are not explained above with reference to FIGS. 1 to 10A will be mainly explained below.

For reference, FIG. 11 is a cross sectional view taken on line A-A of FIG. 1.

Referring to FIG. 11, in a semiconductor device according to some example embodiments, the first gate spacers 131, 132 may include first stress spacers 131c, 132c.

The first stress spacers 131c, 132c may be formed on the first oxide spacers 131b, 132b. The first stress spacers 131c, 132c are not formed on the second oxide spacers 231b, 232b. The first stress spacers 131c, 132c may be formed conformally on the second oxide spacers 231b, 232b. Moreover, as illustrated, the first stress spacers 131c, 132c may be formed along an upper surface of the first source/drain region 140. Note that, in some example embodiments, no portion of the first stress spacers 131c, 132c may be formed along the upper surface of the first source/drain region 140.

The first stress spacers 131c, 132c may exert the tensile stress to the first gate electrode 120. That is, the first gate electrode 120 may have a shape that has a positive slope with the sidewall, according to the tensile stress of the first stress spacers 131c, 132c.

For example, the first stress spacers 131c, 132c may include silicon nitride film.

The second gate spacers 231, 232 may include second compressive stress spacers 231d, 232d.

The second compressive stress spacers 231d, 232d may be formed on the second oxide spacers 231b, 232b. The second compressive stress spacers 231d, 232d are not formed on the first oxide spacers 131b, 132b. The second compressive stress spacers 231d, 232d may be formed conformally on the second oxide spacers 231b, 232b. Moreover, as illustrated, the second compressive stress spacers 231d, 232d may be formed along the upper surface of the first source/drain region 140. Note that, in some example embodiments, no portion of the second compressive stress spacers 231d, 232d may be formed along the upper surface of the first source/drain region 140.

The second compressive stress spacers 231d, 232d may exert compressive stress to the second gate electrode 220. That is, the second gate electrode 220 may have such a shape that has a negative slope with the sidewall, according to the compressive stress of the second compressive stress spacers 231d, 232d.

For example, the second compressive stress spacers 231d, 232d may include silicon oxide film, but not limited thereto. The second compressive stress spacers 231d, 232d may include the same material as the interlayer insulating film 180. Accordingly, in FIG. 11, the second compressive stress spacers 231d, 232d are indicated in dotted lines. That is, the second compressive stress spacers 231d, 232d may not be distinguished from the interlayer insulating film 180.

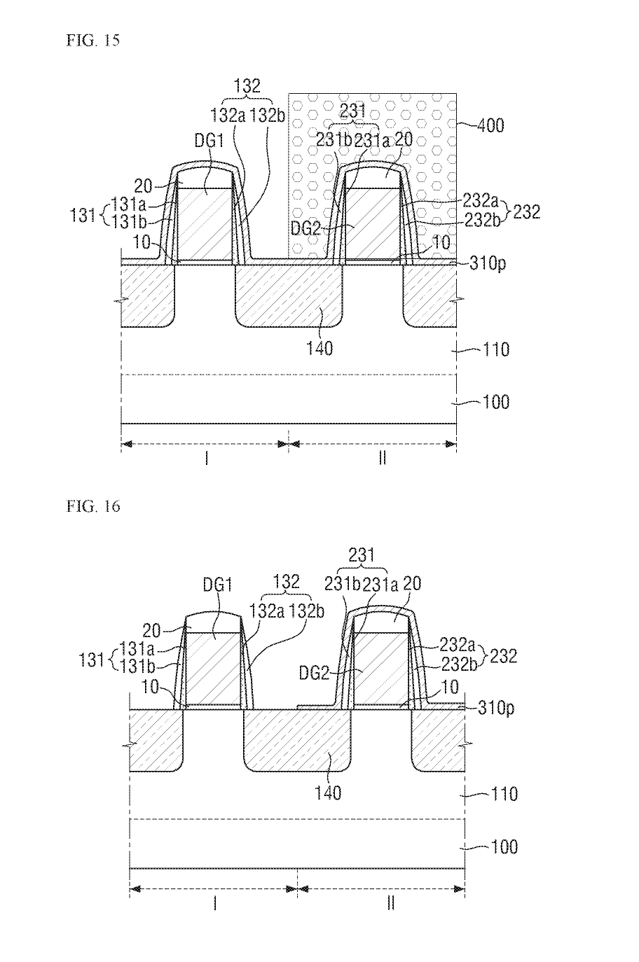

FIG. 12 is a view provided to explain a semiconductor device according to some example embodiments. For convenience of explanation, differences that are not explained above with reference to FIGS. 1 to 11 will be mainly explained below.

For reference, FIG. 12 is a cross sectional view taken on line A-A of FIG. 1.

Referring to FIG. 12, in a semiconductor device according to some example embodiments, the first gate spacers 131, 132 may include first stress spacers 131c, 132c, and the second gate spacers 231, 232 may include the second stress spacers 231c, 232c.

The first stress spacers 131c, 132c may be formed on the first oxide spacers 131b, 132b. The second stress spacers 231c, 232c may be formed on the second oxide spacers 231b, 232b. The thicknesses T1, T3 of the first stress spacers 131c, 132c may be thicker than the thickness T2, T4 of the second stress spacers 231c, 232c.

The first stress spacers 131c, 132c may be connected with the second stress spacers 231c, 232c. Specifically, the first stress spacer 132c and the second stress spacer 231c may be connected with each other. Because the first stress spacers 131c, 132c have different thicknesses from the second stress spacers 231c, 232c, there may be stepped thickness formed on a connecting portion between the first stress spacers 131c, 132c and the second stress spacers 231c, 232c. The ‘stepped thickness’ as used herein may be defined so as to refer to a portion where two sides of different thicknesses meet.

The first stress spacers 131c, 132c and the second stress spacers 231c, 232c may exert the tensile stress to the first gate electrode 120 and the second gate electrode 220, respectively. Note that, because the first stress spacers 131c, 132c and the second stress spacers 231c, 232c have different thicknesses, the tensile stress exerted on the first gate electrode 120 may be greater than the tensile stress exerted on the second gate electrode 220.

Accordingly, a ratio of the width S1t of the upper surface of the first gate electrode to the width S1b of the lower surface of the first gate electrode may be greater than a ratio of the width S2t of the upper surface of the second gate electrode to the width S2b of the lower surface of the second gate electrode. While FIG. 12 illustrates that the ratio of the width S2t of the upper surface of the second gate electrode to the width S2b of the lower surface of the second gate electrode is less than 1, example embodiments are not limited thereto. When the ratio of the width S2t of the upper surface of the second gate electrode to the width S2b of the lower surface of the second gate electrode is less than 1, the compressive stress may be exerted on the second gate electrode 220 by the interlayer insulating film 180.

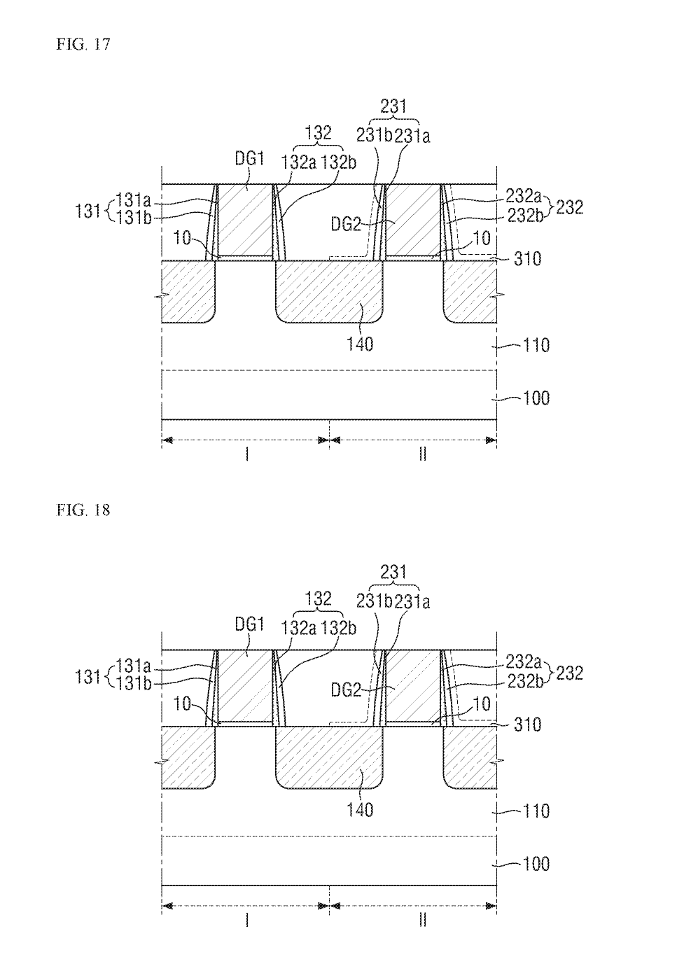

FIG. 13 is a view provided to explain a semiconductor device according to some example embodiments. For convenience of explanation, differences that are not explained above with reference to FIGS. 1 to 12 will be mainly explained below.

For reference, FIG. 13 is a cross sectional view taken on line A-A of FIG. 1.

Referring to FIG. 13, in a semiconductor device according to some example embodiments, the first gate spacers 131, 132 may include first stress spacers 131c, 132c, and the second gate spacers 231, 232 may include the second stress spacers 231c, 232c, and the second compressive stress spacers 231d, 232d.

The second compressive stress spacers 231d, 232d may be formed between the second stress spacers 231c, 232c and the second oxide spacers 231b, 232b. The second compressive stress spacers 231d, 232d may be formed conformally on the second oxide spacers 231b, 232b. Moreover, as illustrated, the second compressive stress spacers 231d, 232d may be formed along the upper surface of the first source/drain region 140. Note that, in some example embodiments, no portion of the second compressive stress spacers 231d, 232d may be formed along the upper surface of the first source/drain region 140.

The second compressive stress spacers 231d, 232d may exert compressive stress to the second gate electrode 220. That is, the second gate electrode 220 may have such a shape that has a negative slope with the sidewall, according to the compressive stress of the second compressive stress spacers 231d, 232d.

The second compressive stress spacers 231d, 232d may include the same material as the second oxide spacers 231b, 232b. That is, the second compressive stress spacers 231d, 232d may include silicon oxide, for example. Accordingly, the second compressive stress spacers 231d, 232d combined with the second oxide spacers 231b, 232b may be defined to be third oxide spacers 231b′, 232b′.

The thickness G1 of the first stress spacers 131b, 132b may be less than the thickness G2 of the third oxide spacers 231b′, 232b′. That is, while the thicknesses of the first oxide spacers 131b, 132b and the second oxide spacers 231b, 232b may be same or similar, the thicknesses of the third oxide spacers 231b′, 232b′added with the second compressive stress spacers 231d, 232d may be thicker than the above.

The first stress spacers 131c, 132c may be connected with the second stress spacers 231c, 232c. Specifically, the first stress spacer 132c and the second stress spacer 231c may be connected with each other.

The first stress spacers 131c, 132c may be formed directly on the first source/drain region 140. In contrast, the second stress spacers 231c, 232c may be formed on the second compressive stress spacers 231d, 232d positioned on the first source/drain region 140. Accordingly, a stepped height may be formed on a portion where the first stress spacers 131c, 132c and the second stress spacers 231c, 232c meet. The ‘stepped height’ as used herein may be defined so as to refer to a portion where two sides having upper surfaces of different heights from each other meet.

The first stress spacers 131c, 132c and the second stress spacers 231c, 232c may exert the tensile stress to the first gate electrode 120 and the second gate electrode 220, respectively. Note that, because the second compressive stress spacers 231d, 232d exert the compressive stress to the second gate electrode 220, the total tensile stress exerted on the first gate electrode 120 may be greater than the total tensile stress exerted on the second gate electrode 220. In contrast, the total compressive stress exerted on the first gate electrode 120 may be less than the total compressive stress exerted on the second gate electrode 220.

Accordingly, a ratio of the width S1t of the upper surface of the first gate electrode to the width S1b of the lower surface of the first gate electrode may be greater than a ratio of the width S2t of the upper surface of the second gate electrode to the width S2b of the lower surface of the second gate electrode. While FIG. 12 illustrates that the ratio of the width S2t of the upper surface of the second gate electrode to the width S2b of the lower surface of the second gate electrode is less than 1, example embodiments are not limited thereto. When the ratio of the width S2t of the upper surface of the second gate electrode to the width S2b of the lower surface of the second gate electrode is less than 1, the compressive stress may be exerted on the second gate electrode 220 by the interlayer insulating film 180.

Hereinbelow, a method of fabricating a semiconductor device according to some example embodiments will be described with reference to FIGS. 1, 2 and 14 to 19. Elements or operations overlapping with those described above with reference to FIGS. 1 to 13 will be mentioned as briefly as possible or omitted for the sake of brevity.

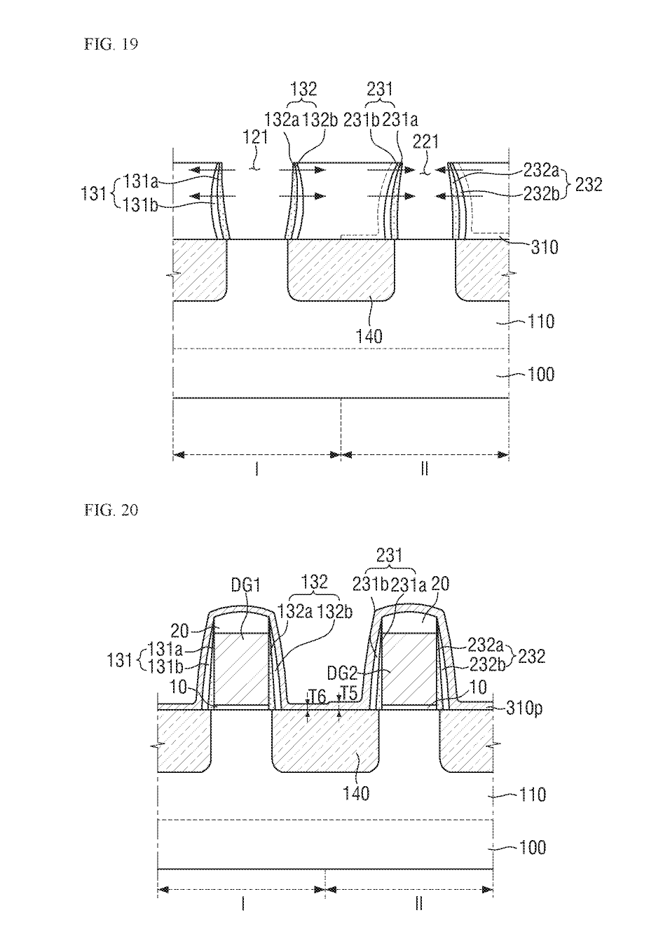

FIGS. 14 to 19 are views illustrating intermediate stages of fabrication, provided to explain a method of fabricating a semiconductor device according to some example embodiments.

Referring to FIG. 14, dummy gate insulating film 10, first dummy gate electrode DG1, second dummy gate electrode DG2, capping pattern 20, first source/drain region 140, first gate spacers 131, 132 and second gate spacers 231, 232 are formed, and liner 310P is then formed.

Referring to FIG. 1, on the substrate 100, the first fin-type pattern 110 may extend in a first direction X1, and the first dummy gate electrode DG1 and the second dummy gate electrode DG2 may extend in a second direction Y1 different from the first direction X1.

Like the first dummy gate electrode DG1 and the second dummy gate electrode DG2, the dummy gate insulating film 10 may extend in the second direction Y1. The first dummy gate electrode DG1 and the second dummy gate electrode DG2 may be formed on the dummy gate insulating film 10.

The capping pattern 20 may be formed on the first dummy gate electrode DG1 and the second dummy gate electrode DG2. The capping pattern 20 may be a mask to pattern the first dummy gate electrode DG1 and the second dummy gate electrode DG2. However, example embodiments are not limited to the example given above.

The first gate spacers 131, 132 and the second gate spacers 231, 232 may be formed on the sidewalls of the first dummy gate electrode DG1 and the second dummy gate electrode DG2, respectively. The first gate spacers 131, 132 and the second gate spacers 231, 232 may also be formed on the sidewalls of the capping pattern 20.

First source/drain regions 140 may be formed on both sides of the first gate electrode 120 and on both sides of the second gate electrode 220.

The liner 310P may be formed on the first source/drain region 140, the first gate spacers 131, 132, the second gate spacers 231, 232, and the capping pattern 20. The liner 310P may be formed conformally on the first source/drain region 140, the first gate spacers 131, 132, the second gate spacers 231, 232, and the capping pattern 20.

For example, the liner 310P may include silicon. The liner 310P may be changed into silicon oxide film by a subsequent thermal treatment.

Next, referring to FIG. 15, a barrier film 400 is formed in the second region II.

The barrier film 400 may be formed on a portion of the liner 310P, that is, formed on the liner 310P positioned in the second region II, and may expose the liner 310P positioned in the first region I.

Next, referring to FIG. 16, the liner 310P is removed from the first region I and the barrier film 400 is removed.

Accordingly, the liner 310P may be present in the second region II, but not present in the first region I.

Next, referring to FIG. 17, the interlayer insulating film 180 is formed in the first region I and the second region II.

In the first region L the interlayer insulating film 180 may be formed so as to cover the first dummy gate electrode DG1, the first gate spacers 131, 132, and the capping pattern 20. In the second region II, the interlayer insulating film 180 may be formed so as to cover the second dummy gate electrode DG2, the second gate spacers 231, 232, the capping pattern 20, and the liner 310P.

Next, the liner 310P is changed into the second compressive stress spacers 231d, 32d by thermal treatment.

The liner 310P may include silicon, and the silicon may be changed into silicon oxide by the thermal treatment. The second compressive stress spacers 231d, 232d may be formed, as the silicon of the liner 310P is changed into silicon oxide, thus expanding in volume. Accordingly, the second compressive stress spacers 231d, 232d may exert the compressive stress on the second gate spacers 231, 232 and the second dummy gate electrode DG2.

Next, referring to FIG. 18, the interlayer insulating film 180, the first gate spacers 131, 132, the second gate spacers 231, 232, the second compressive stress spacers 231d, 232d, and the capping pattern 20 are planarized, thus exposing the first dummy gate electrode DG1 and the second dummy gate electrode DG2.

At this time, the capping pattern 20 may be entirely removed, and the second compressive stress spacers 231d, 232d, the first gate spacers 131, 132 and the second gate spacers 231, 232 may be partially removed.

Next, referring to FIG. 19, the first dummy gate electrode DG1 and the second dummy gate electrode DG2 are removed.

The first trench 121 may be formed in accordance with the removal of the first dummy gate electrode DG1, and the second trench 221 may be formed in accordance with the removal of the second dummy gate electrode DG2. The second trench 221 may be shaped such that the upper portion is narrowed due to the compressive stress by the second compressive stress spacers 231d, 232d.

The first trench 121 may be shaped such that the upper portion is widened as illustrated, when the interlayer insulating film 180 has tensile stress characteristic. However, example embodiments are not limited to the above. Accordingly, the first trench 121 may be shaped such that the side surface is not inclined in some other example embodiments.

Next, referring to FIGS. 1 and 2, the first gate electrode 120 and the second gate electrode 220 may be formed in the first trench 121 and the second trench 221, respectively.

In this case, the first gate electrode 120 and the second gate electrode 220 may be different conductivity types from each other. Specifically, the first gate electrode 120 may be an N-type, and the second gate electrode 220 may be a P-type.

The sidewall of the first gate electrode 120 and the sidewall of the second gate electrode 220 may have a positive slope and a negative slope, respectively, along the shapes of the first trench 121 and the second trench 221.

Hereinbelow, a method of fabricating a semiconductor device according to some example embodiments will be explained with reference to FIGS. 14, 17 to 19, and 20. Elements or operations overlapping with those described above with reference to FIGS. 1 to 19 will be mentioned as briefly as possible or omitted for the sake of brevity.

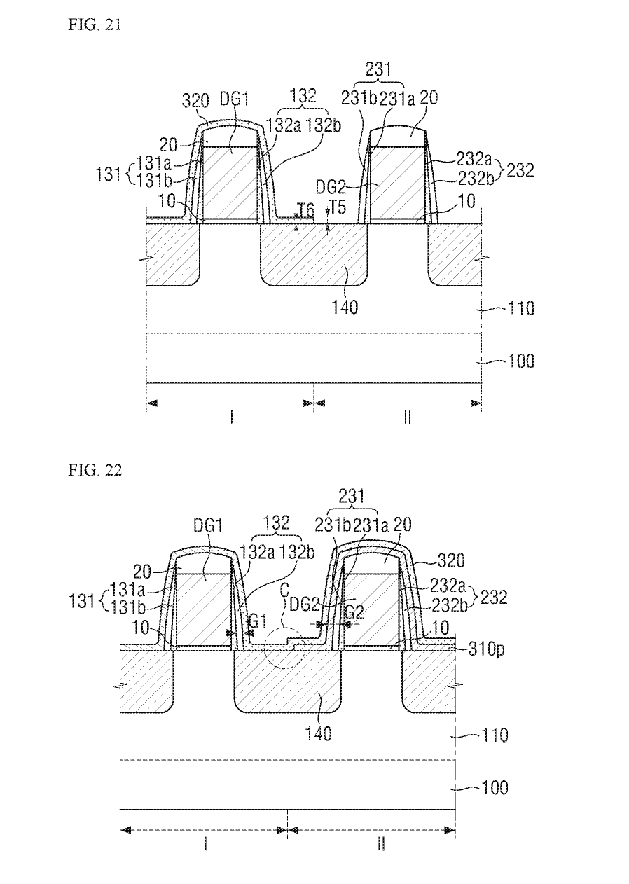

FIG. 20 is a view illustrating intermediate stages of fabrication, provided to explain a method of fabricating a semiconductor device according to some example embodiments. FIG. 20 may involve a process performed after FIG. 14.

Referring to FIG. 20, the thickness of the liner 310P in the first region I and the second region II may be formed differently.

The thickness T6 of the liner 310P in the first region I may be thinner than the thickness T5 of the liner 310P in the second region II. Accordingly, the stepped thickness may be formed at a boundary between the first region I and the second region II.

The thickness of the liner 310P may be varied by using the etch process and the deposit process in various manners. For example, the liner 310P in the second region II may be removed, while a thicker liner 310P may be re-deposited in the second region II. Alternatively, the liner 310P in the first region I may be selectively etched. However, example embodiments are not limited to the example given above.

Next, according to the stages as illustrated FIGS. 17 to 19, semiconductor devices may be formed, in which different stresses are exerted.

Hereinbelow, a method of fabricating a semiconductor device according to some example embodiments will be explained with reference to FIGS. 11, 17 to 19, and 21. Elements or operations overlapping with those described above with reference to FIGS. 1 to 20 will be mentioned as briefly as possible or omitted for the sake of brevity.

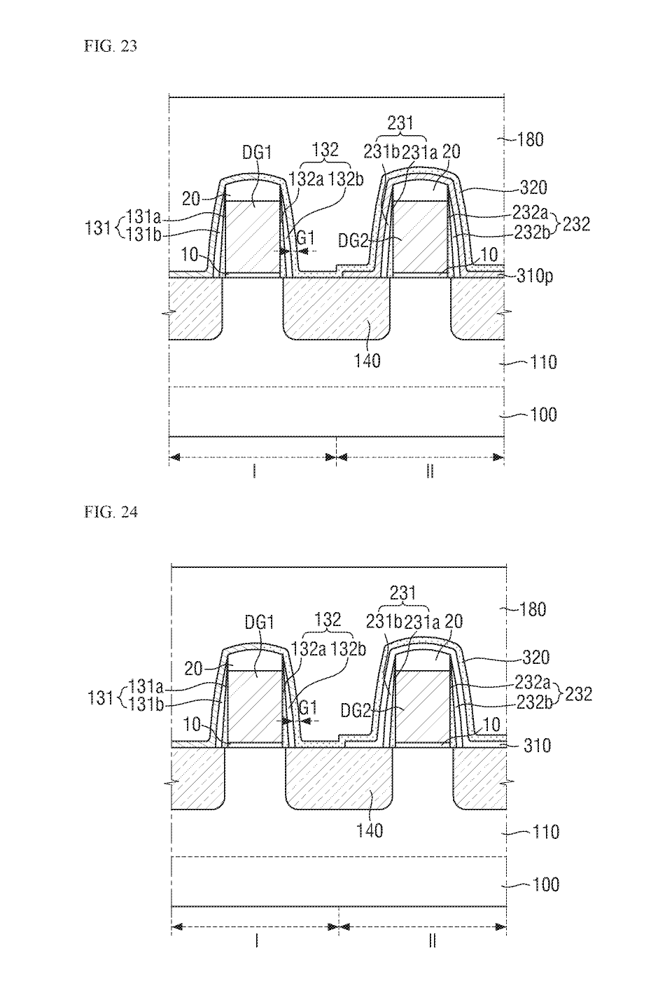

FIG. 21 is a view illustrating intermediate stages of fabrication, provided to explain a method of fabricating a semiconductor device according to some example embodiments.

Referring to FIG. 21, a tensile liner 320 is formed in the first region I.

The tensile liner 320 may be conformally formed on the first oxide spacers 131b, 132b. The tensile liner 320 may not be formed in the second region II.

Next, the stages of FIGS. 17 to 19 may be exactly performed. At this time, the tensile liner 320 may be imparted with the tensile stress by the thermal treatment. Accordingly, the tensile stress exerted to the first region I and the second region II may vary.

Next, referring to FIG. 11, the first gate electrode 120 and the second gate electrode 220 may be formed in the first trench 121 and the second trench 221, respectively.

In this case, the first gate electrode 120 and the second gate electrode 220 may be different conductivity types from each other. Specifically, the first gate electrode 120 may be an N-type, and the second gate electrode 220 may be a P-type.

The sidewall of the first gate electrode 120 and the sidewall of the second gate electrode 220 may have a positive slope and a negative slope, respectively, along the shapes of the first trench 121 and the second trench 221. However, example embodiments are not limited to the example given above.

Hereinbelow, a method of fabricating a semiconductor device according to some example embodiments will be explained with reference to FIGS. 13 and 22 to 25. Elements or operations overlapping with those described above with reference to FIGS. 1 to 21 will be mentioned as briefly as possible or omitted for the sake of brevity.

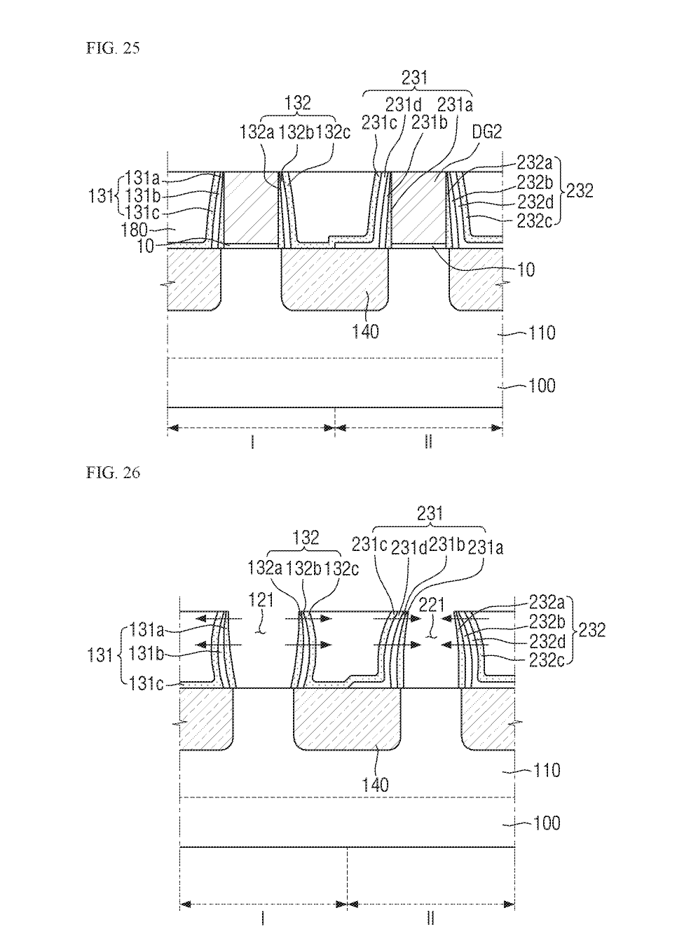

FIGS. 22 to 25 are views illustrating intermediate stages of fabrication, provided to explain a method of fabricating a semiconductor device according to some example embodiments.

Referring to FIG. 22, the liner 310P and the tensile liner 320 are formed.

The liner 310P may be formed in the second region IL, but not formed in the first region I. The tensile liner 320 may be formed in the first region I and the second region II. The tensile liner 320 may be formed on the liner 310P. Because the liner 310P is not present in the first region I, the tensile liner 320 may have a stepped height at a boundary C between the first region I and the second region II.

Next, referring to FIG. 23, the interlayer insulating film 180 is formed in the first region I and the second region II.

In the first region I, the interlayer insulating film 180 may be formed so as to cover the first dummy gate electrode DG1, the first gate spacers 131, 132, the tensile liner 320, and the capping pattern 20. In the second region II, the interlayer insulating film 180 may be formed so as to cover the second dummy gate electrode DG2, the second gate spacers 231, 232, the capping pattern 20, the liner 310P, and the tensile liner 320.

Next, referring to FIG. 24, the liner 310P is changed into the first stress spacers 131c, 132c by thermal treatment.

The tensile liner 320 may include silicon nitride, and the first stress spacers 131c, 132c may be formed, as the silicon nitride decreases in volume by the thermal treatment. Accordingly, the first stress spacers 131c, 132c may exert the tensile stress on the first dummy gate electrode DG1.

Next, referring to FIG. 25, the interlayer insulating film 180, the first gate spacers 131, 132, the second gate spacers 231, 232, the first stress spacers 131c, 132c, and the capping pattern 20 are planarized, thus exposing the first dummy gate electrode DG1 and the second dummy gate electrode DG2.

At this time, the capping pattern 20 may be entirely removed, and the first stress spacers 131c, 132c, the first gate spacers 131, 132 and the second gate spacers 231, 232 may be partially removed.

Next, referring to FIG. 26, the first dummy gate electrode DG1 and the second dummy gate electrode DG2 are removed.

The first trench 121 may be formed in accordance with the removal of the first dummy gate electrode DG1, and the second trench 221 may be formed in accordance with the removal of the second dummy gate electrode DG2. The second trench 221 may be shaped such that the upper portion is widened due to the tensile stress by the first stress spacers 131c, 132c.

The first trench 121 may be shaped such that the upper portion is narrowed as illustrated, when the interlayer insulating film 180 has compressive stress characteristic. However, example embodiments are not limited to the above. Accordingly, the first trench 121 may be shaped such that the side surface is not inclined in some other example embodiments.

Next, referring to FIG. 13, the first gate electrode 120 and the second gate electrode 220 may be formed in the first trench 121 and the second trench 221, respectively.

In this case, the first gate electrode 120 and the second gate electrode 220 may be different conductivity types from each other. Specifically, the first gate electrode 120 may be an N-type, and the second gate electrode 220 may be a P-type.

The sidewall of the first gate electrode 120 and the sidewall of the second gate electrode 220 may have a positive slope and a negative slope, respectively, along the shapes of the first trench 121 and the second trench 221.

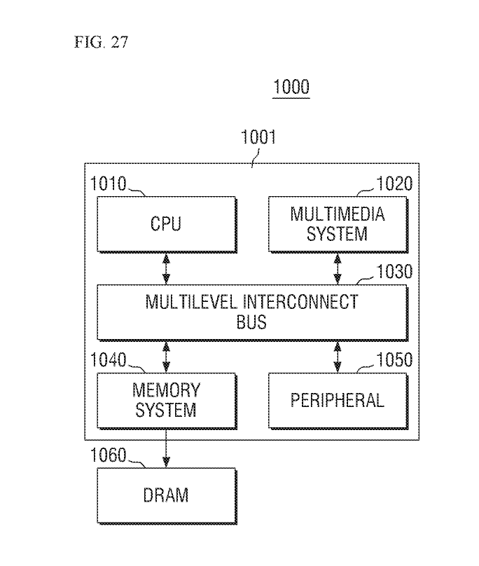

FIG. 27 is a block diagram of a SoC system including a semiconductor device according to example embodiments.

Referring to FIG. 27, a System on Chip (SoC) system 1000 includes an application processor 1001 and a dynamic random-access memory (DRAM) 1060.

The application processor 1001 may include a central processing unit (CPU) 1010, a multimedia system 1020, a bus 1030, a memory system 1040 and a peripheral circuit 1050.

The CPU 1010 may include at least one processor. The processor may be implemented by at least one semiconductor chip disposed on a printed circuit board. The processor may be an arithmetic logic unit, a digital signal processor, a microcomputer, a field programmable array, a programmable logic unit, a microprocessor or any other device capable of responding to and executing instructions in a defined manner.

The CPU 1010 may perform arithmetic operation necessary for driving of the SoC system 1000. In some example embodiments, the CPU 1010 may be configured on a multi-core environment which includes a plurality of cores.

The multimedia system 1020 may perform a variety of multimedia functions on the SoC system 1000. Such multimedia system 1020 may include a three-dimensional (3D) engine module, a video codec, a display system, a camera system, a post-processor, and so on.

The bus 1030 may be used for exchanging data communication among the CPU 1010, the multimedia system 1020, the memory system 1040 and the peripheral circuit 1050. In some example embodiments, the bus 1030 may have a multi-layer structure. Specifically, an example of the bus 1030 may be a multi-layer advanced high-performance bus (AHB), or a multi-layer advanced eXtensible interface (AXI), although example embodiments are not limited herein.

The memory system 1040 may provide environments necessary for the application processor 1001 to connect to an external memory (e.g., DRAM 1060) and perform high-speed operation. In some example embodiments, the memory system 1040 may include a separate controller (e.g., DRAM controller) to control an external memory (e.g., DRAM 1060).

The peripheral circuit 1050 may provide environments necessary for the SoC system 1000 to have a seamless connection to an external device (e.g., main board). Accordingly, the peripheral circuit 1050 may include a variety of interfaces to allow compatible operation with the external device connected to the SoC system 1000.

The DRAM 1060 may function as an operation memory necessary for the operation of the application processor 1001. In some example embodiments, the DRAM 1060 may be arranged externally to the application processor 1001, as illustrated. Specifically, the DRAM 1060 may be packaged into a package on package (PoP) type with the application processor 1001.

At least one of the above-mentioned components of the SoC system 1000 may include at least one of the semiconductor devices according to the example embodiments explained above.

While example embodiments of the inventive concepts have been particularly shown and described with reference to some example embodiments thereof, it will be understood by those of ordinary skill in the art that various changes in form and details may be made therein without departing from the spirit and scope of the example embodiments of the inventive concepts as defined by the following claims. It is therefore desired that the example embodiments be considered in all respects as illustrative and not restrictive, reference being made to the appended claims rather than the foregoing description to indicate the scope of the example embodiments.

What is claimed is:

1. A semiconductor device, comprising:
a first gate electrode on a substrate, the first gate electrode having a first ratio of a width of an upper surface thereof to a width of a lower surface thereof;
a second gate electrode on the substrate, the second gate electrode having a second ratio of a width of an upper surface thereof to a width of a lower surface thereof such that the second ratio is less than the first ratio;
a first gate spacer on a sidewall of the first gate electrode;
a second gate spacer on a sidewall of the second gate electrode; and
an interlayer insulating film at least partially covering the first gate spacer and the second gate spacer.

2. The semiconductor device of claim 1, wherein the first ratio is greater than or equal to 1, and the second ratio is less than or equal to 1.

3. The semiconductor device of claim 1, wherein the first ratio and the second ratio are greater than or equal to 1.

4. The semiconductor device of claim 1, wherein the first ratio and the second ratio are less than or equal to 1.

5. The semiconductor device of claim 1, wherein the first gate electrode is an N-type gate electrode, and the second gate electrode is a P-type gate electrode.

6. The semiconductor device of claim 5, wherein
the first gate electrode includes an N-type work function metal, and
the second gate electrode includes an N-type work function metal and a P-type work function metal.

7. The semiconductor device of claim 1, wherein a width of the first gate electrode gradually decreases from the upper surface of the substrate to the upper surface of the first gate electrode.

8. The semiconductor device of claim 7, wherein a width of the second gate electrode gradually increases from the upper surface of the substrate to the upper surface of the second gate electrode.

9. The semiconductor device of claim 1, wherein the first gate spacer comprises:
a first nitride spacer on the sidewall of the first gate electrode;
a first oxide spacer on the first nitride spacer; and
a first stress spacer on the first oxide spacer.

10. The semiconductor device of claim 9, wherein the second gate spacer comprises:
a second nitride spacer on the sidewall of the second gate electrode;
a second oxide spacer on the second nitride spacer; and
a second stress spacer on the second oxide spacer.

11. The semiconductor device of claim 10, wherein a thickness of the first oxide spacer is different than a thickness of the second oxide spacer.

12. The semiconductor device of claim 10, wherein the first stress spacer and the second stress spacer are connected via stepped connecting portions.

13. A semiconductor device, comprising:
a first gate electrode on a substrate such that a width of the first gate electrode increases with increasing distance from the substrate;
a second gate electrode on the substrate such that a width of the second gate electrode decreases with increasing distance from the substrate;
a first gate spacer on a sidewall of the first gate electrode, the first gate spacer configured to exert a first tensile stress on the first gate electrode;
a second gate spacer on a sidewall of the second gate electrode, the second gate spacer configured to exert a second tensile stress on the second gate electrode such that the first tensile stress exerted on the first gate electrode is greater than the second tensile stress exerted on the second gate electrode; and
an interlayer insulating film at least partially covering the first gate spacer and the second gate spacer.

14. The semiconductor device of claim 13, wherein the interlayer insulating film is configured to exert a compressive stress on the second gate electrode.

15. The semiconductor device of claim 13, wherein the first gate spacer comprises:
a first nitride spacer on the sidewall of the first gate electrode;
a first oxide spacer on the first nitride spacer; and
a first stress spacer on the first oxide spacer, the first stress spacer configured to exert the first tensile stress on the first gate electrode.

16. A semiconductor device, comprising:
a first gate spacer on sidewalls of a first gate electrode such that the first gate spacer is configured to exert a first tensile stress on the first gate electrode;
a second gate spacer on sidewalls of a second gate electrode such that the first gate spacer is configured to exert a second tensile stress on the second gate electrode; and
an interlayer insulating film at least partially covering the first gate spacer and the second gate spacer such that the interlayer insulating film is configured to exert a first compressive stress on the first gate electrode and a second compressive stress on the second gate electrode.

17. The semiconductor device of claim 16, wherein the first gate electrode and the second gate electrode each have a lower surface on a substrate such that a first width associated with the first gate electrode increases from the lower surface to an upper surface thereof, and a second width associated with the second gate electrode decreases from the lower surface to an upper surface thereof.

18. The semiconductor device of claim 17, wherein the first tensile stress is greater than the second tensile stress such that the first width increases and the second width decreases as a distance increases from the substrate to the upper surfaces of the first gate electrode and the second gate electrode, respectively.

19. The semiconductor device of claim 18, wherein the first tensile stress is greater than the first compressive stress.

20. The semiconductor device of claim 18, wherein the first gate electrode is doped with an N-type material and the second gate electrode is doped with a P-type material such that the first gate electrode and the second gate electrode experience a net tensile stress and a net compressive stress, respectively.
